(19) United States
(12) Patent Application Publication
(10) Pub. No.: US 2006/0285288 A1
(43) Pub. Date: Dec. 21, 2006

(54) Electric device

(75) Inventors: Shih-Hao Yeh, Taipei (TW); Chi-Hwa Ho, Taipei (TW); Chi-Hung Chen, Taipei (TW); Sheng Hong Wang, Taipei (TW)

Correspondence Address: BIRCH STEWART KOLASCH & BIRCH, PO BOX 747, FALLS CHURCH, VA, 22040-0747, US

(73) Assignee: ASUSTeK COMPUTER INC.

(21) Appl. No.: 11/452,395

(22) Filed: Jun. 14, 2006

(30) Foreign Application Priority Data
Jun. 16, 2005 (TW) 094119938

(51) Int. Cl. G06F 1/16; H05K 5/00

(52) U.S. Cl. 361/685

(57) ABSTRACT

An electric device includes a first housing, a second housing, an ODD main body and an ODD protecting element. The first housing and the second housing form a containing space. The ODD main body is located in the containing space and is disposed on the second housing. At least one part of the ODD protecting element connects with the second housing. Furthermore, the ODD protecting element covers the ODD main body.

### BACKGROUND OF THE INVENTION

1. Field of Invention

The invention relates to an electric device and, in particular, to an electric device equipped with a thin optical disk drive (ODD).

2. Related Art

In a notebook computer, a predetermined distance between an ODD and a housing of the notebook computer has to be kept in order to prevent the press of a user or an external force applied to the housing from damaging the ODD. That is, a predetermined space above the ODD has to be left in order to prevent the ODD from being pressed when the housing is deformed.

Referring to FIGS. 1 and 2, a notebook computer 1 includes an ODD 11, an upper housing 12, a lower housing 13 and a keyboard 14. The upper housing 12 and the lower housing 13 form a containing space. The ODD 11 is disposed in the containing space. The keyboard 14 is mounted on the upper housing 12. The ODD 11 includes a cover 111, a main body 112 and a base 113. The main body 112 is mounted on the base 113 and the cover 111 is mounted on the main body 112 for protecting the main body 112. In addition, the base 113 is mounted on the lower housing 13. Herein, a preserved space is left between the upper housing 12 and the cover 111 in order to prevent the ODD 11 from being damaged by the external force when the upper housing 12 is pressed by the external force. The preserved space has a dimension of about 1 to 2 millimeters.

In addition, the ODD 11 may be classified into a thin type ODD having a height of about 12.7 millimeters, and an ultra-thin type ODD having a height of about 9.5 millimeters. Compared the thin type with the ultra-thin type, an internal element, such as a spindle motor or an optical pickup head, in the ultra-thin type ODD has a smaller volume but a higher cost. If the manufacturer wants to reduce the height of the notebook computer by mounting the ultra-thin type ODD in the notebook computer, the manufacturer must spend a higher cost. If the thin type ODD is used, the overall thickness of the notebook computer increases, and the trend of miniaturization cannot be satisfied.

Thus, it is an important subject of the invention to provide an ODD protecting element capable of preventing the ODD in the electric device from being damaged by the external force, such that the preserved space between the ODD and the upper housing of the notebook computer may be reduced and the overall height of the notebook computer may be reduced accordingly.

### SUMMARY OF THE INVENTION

In view of the foregoing, the invention is to provide an electric device having a build-in protection structure for an ODD.

To achieve the above, an embodiment of the invention provides an electric device including a first housing, a second housing, an ODD main body and an ODD protecting element. The second housing and the first housing form a containing space. The ODD main body is located in the containing space and disposed on the second housing. At least one part of the ODD protecting element connects with the second housing. Furthermore, the ODD protecting element covers the ODD main body.

To achieve the above, the embodiment of the invention also provides an electric device including a first housing, a second housing, an ODD main body and an ODD protecting element. The second housing and the first housing form a containing space. The ODD main body is located in the containing space and disposed on the second housing. At least one part of the ODD protecting element connects with the first housing. The ODD protecting element covers the ODD main body.

To achieve the above, the embodiment of the invention further provides an electric device including a first housing, a second housing, an ODD main body and an ODD protecting element. The first housing and the second housing form a containing space. The ODD main body is located in the containing space and disposed on the second housing. The ODD protecting element is located between the first housing and the ODD main body. The electric device is characterized in that a minimum distance from the ODD protecting element to the first housing is smaller than 1 millimeter.

Furthermore, the embodiment of the invention also provides an electric device including a first housing, a second housing, an ODD main body, and a protecting element. The second housing and the first housing form a containing space. The ODD main body is located in the containing space and disposed on the second housing. The protecting element contacts the first housing to partially transfer an external force, which is applied from the first housing to the protecting element, to the second housing so as to buffer the external force and to prevent the ODD main body from being damaged.

As mentioned above, the electric device has the ODD protecting element, and at least one part of the ODD protecting element connects with the second housing. Thus, the ODD protecting element can partially transfer the external force, which is applied form the first housing to the ODD protecting element, to the second housing so as to buffer the external force exerted on the first housing, to prevent the ODD main body from being damaged, and thus to prevent the ODD from being damaged. Meanwhile, the gap between the upper cover and the ODD may be reduced or no gap has to be left therebetween according to such a design according to the invention. Thus, the electric device is equipped with an ODD (e.g., a thin-type ODD with the dimension of 12.7 millimeters) having a lower cost but a higher height, the overall height of the electric device of the invention may approximate to the height of the conventional electric device equipped with the ultra-thin type ODD having the dimension of 9.5 millimeters. As mentioned above, the electric device may be equipped with an ODD having a larger thickness but a lower cost without departing from the requirement of the miniaturized product. Hence, the cost of the electric device of the embodiment is much lower than that of the conventional electric device equipped with the ultra-thin type ODD.

### BRIEF DESCRIPTION OF THE DRAWINGS

The invention will become more fully understood from the detailed description given herein below illustration only, and thus is not limitative of the present invention, and wherein:

FIG. 1 is an exploded view showing a conventional notebook computer;

FIG. 2 is an assembled view showing the conventional notebook computer;

FIGS. 3 and 9 are exploded views showing electric devices according to embodiments of the invention;

FIGS. 4 and 10 are assembled views showing the electric devices according to the embodiments of the invention;

FIGS. 5 to 8 are front views showing the electric device according to the embodiments of the invention; and

FIGS. 11 to 12 are front views showing an electric device according to another embodiment of the invention.

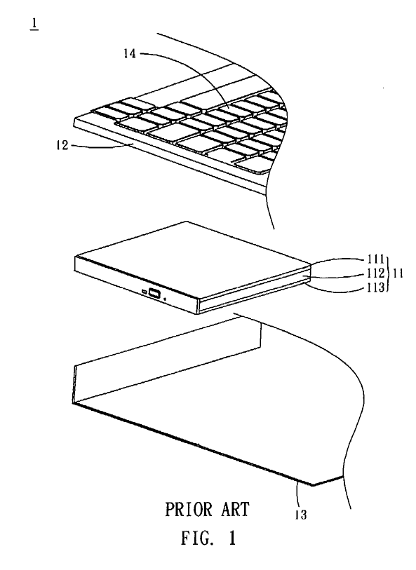

### DETAILED DESCRIPTION OF THE INVENTION

The present invention will be apparent from the following detailed description, which proceeds with reference to the accompanying drawings, wherein the same references relate to the same elements.

The electric device according to the preferred embodiment of the invention includes a first housing, a second housing, an ODD main body and an ODD protecting element. The second housing and the first housing form a containing space. The ODD main body is located in the containing space and disposed on the second housing. At least one part of the ODD protecting element connects with the first housing or the second housing, and the ODD protecting element covers the ODD main body.

Because the electric device according to the preferred embodiment of the invention may be a notebook computer, a tablet computer or an optical disk video player, which has the build-in optical disk drive. For the sake of simplicity, the notebook computer is illustrated as examples in the following embodiments.

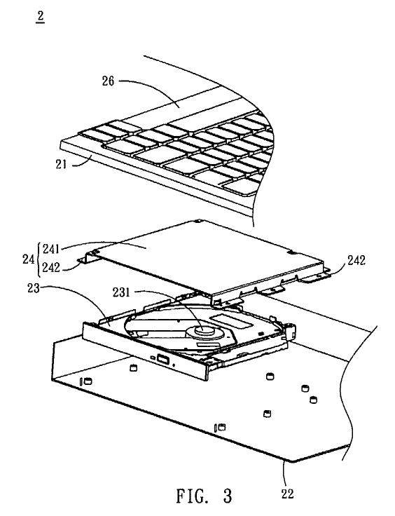

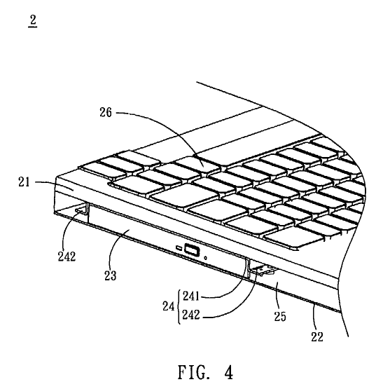

As shown in FIGS. 3, 4 and 5, an electric device 2 according to the preferred embodiment of the invention is a notebook computer.

In this embodiment, a keyboard 26 may be mounted on a first housing 21, and a second housing 22 and the first housing 21 form a containing space 25. An ODD main body 23 is located in the containing space 25 and disposed on the second housing 22.

In addition, at least one part of an ODD protecting element 24 connects with the second housing 22, and the ODD protecting element 24 covers the ODD main body 23. The ODD protecting element 24 may include a body 241 and a connection portion 242. The body 241 covers the ODD main body 23. The connection portion 242 connects with the body 241, and further connects with the second housing 22. Herein, the thickness of the ODD protecting element 24 is substantially greater than 0.5 millimeters. Furthermore, the ODD protecting element 24 may be composed of a high-intensity material.

In addition, the body 241 and the connection portion 242 of this embodiment may be integrally formed. The ODD protecting element 24 may be a sheet metal, and the connection portion 242 connects with the second housing 22 by way of screwing. In addition, the connection portion 242 may connect with the second housing 22 by way of engaging or riveting. Furthermore, the distance from the first housing 21 to the ODD protecting element 24 may be smaller than 1 millimeter.

In this embodiment, the ODD main body 23 may be fixed to at least one of the first housing 21 and the second housing 22 in order to keep the ODD main body 23 at a fixed position in the notebook computer 2.

When the first housing 21 is pressed by an external force, the external force, which is applied from the first housing 21 to the body 241, may be partially transferred to the second housing 22. Accordingly, the ODD main body 23 is free from being pressed by the first housing 21 because the connection portion 242 connects with the second housing 22. Thus, the distance between the ODD protecting element 24 and the first housing 21 may be reduced. The ODD protecting element 24 may also be attached to the first housing 21 without any gap therebetween.

In such a case, if the notebook computer 2 is equipped with an ODD having a lower cost but a higher height, the ODD main body 23 may be the same as that used in a thin-type ODD. Moreover, the height of the optical disk tray above the spindle motor may be slightly reduced if necessary. Thus, the thickness of the notebook computer 2 of this embodiment extremely approximates to the height of the conventional notebook computer having a build-in ultra-thin type ODD. In addition, the cost of the notebook computer 2 of this embodiment is much smaller than that of the conventional notebook computer having the build-in ultra-thin type ODD.

Furthermore, the ODD protecting element 24 and the ODD main body 23 may be combined into an ODD module to facilitate the selling, shipping or delivering for the ODD manufacturer.

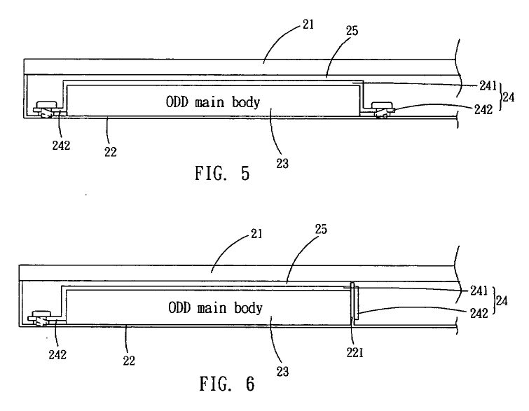

In addition, as shown in FIG. 6, the second housing 22 may have a side body 221 adjacent to the ODD main body 23, and the connection portion 242 connects with the second housing 22 and the side body 221 by way of screwing.

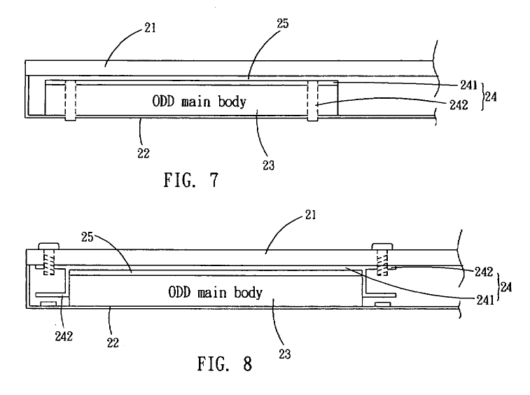

As shown in FIG. 7, the connection portion 242 may also penetrate through the ODD main body 23 and directly connect with the second housing 22.

As shown in FIG. 8, the ODD protecting element 24 in another embodiment connects with the first housing 21 and the connection portion 242 is screwed to the second housing 22. However, the method of connecting the ODD protecting element 24 with the first housing 21 is not limited to that described in this embodiment but may include those for connecting the ODD protecting element 24 with the second housing 22 described in the previous embodiments shown in FIGS. 3 to 7. Thus, detailed descriptions of the method of connecting the ODD protecting element 24 with the first housing 21 will be omitted.

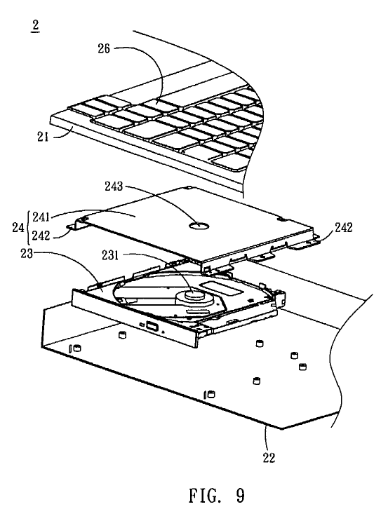

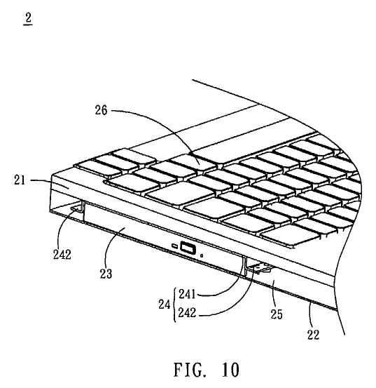

As shown in FIGS. 9 and 10, the ODD protecting element 24 has a through hole 243, and a spindle motor 231 of the ODD main body 23 penetrates through the through hole 243. Thus, the height of the combined ODD main body and ODD protecting element may be reduced.

In addition, the electric device according to still another embodiment of the invention includes a first housing, a second housing, an ODD main body and an ODD protecting element. The first housing and the second housing form a containing space. The ODD main body is located in the containing space and disposed on the second housing. The ODD protecting element is located between the first housing and the ODD main body. A minimum distance from the ODD protecting element to the first housing is smaller than 1 millimeter.

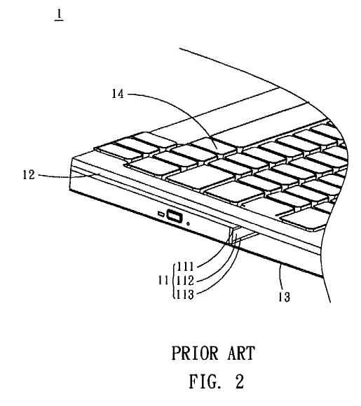

The aspects of this embodiment may be similar to those of the previous embodiment shown in FIGS. 2 to 10. In addition, the functions and features of the elements of this embodiment are the same as those in the above-mentioned embodiments, and the detailed descriptions thereof will be omitted for concise purpose.

In this embodiment, the minimum distance from the ODD protecting element 24 to the first housing 21 is smaller than 1 millimeter. That is, the first housing 21 may be placed on the ODD protecting element 24, or the first housing 21 may touch the ODD protecting element 24 when being pressed. The ODD protecting element 24 supports the first housing 21 because the connection portion 242 contacts the second housing 22. Thus, the ODD main body 23 is free from being pressed by the first housing 21.

Furthermore, the electric device according to yet still another embodiment of the invention includes a first housing, a second housing, an ODD main body, and a protecting element. The second housing and the first housing form a containing space. The ODD main body is located in the containing space and disposed on the second housing. The protecting element contacts the first housing to partially transfer an external force, which is applied from the first housing to the protecting element, to the second housing so as to buffer the external force exerted on the first housing and to prevent the ODD main body from being damaged.

The aspects of this embodiment may be similar to those of the previous embodiment shown in FIGS. 2 to 10. In addition, the functions and features of the elements of this embodiment are the same as those in the above-mentioned embodiments, and the detailed descriptions thereof will be omitted for concise purpose.

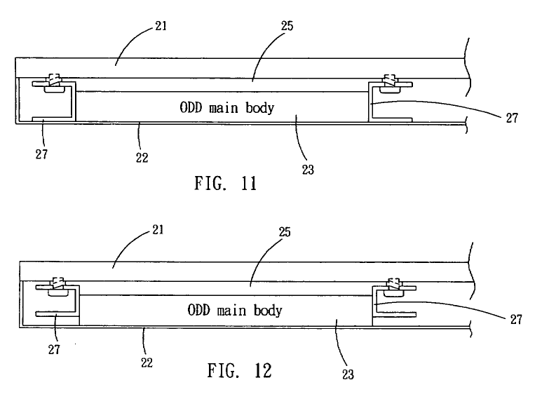

Furthermore, as shown in FIGS. 11 and 12, a protecting element 27 may also be mounted on the first housing 21, or the protecting element 27 and the first housing 21 may be integrally formed. When the first housing 21 bears the external force, the protecting element 27 contacts the second housing 22 and partially transfers the external force, which is applied from the first housing 21 to the protecting element 27, to the second housing 22 so as to buffer the external force exerted on the first housing 21 and prevent the ODD main body 23 from being damaged.

As mentioned above, the electric device of the invention has the ODD protecting element, and at least one part of the ODD protecting element connects with the second housing. Thus, the ODD protecting element can partially transfer the external force, which is applied form the first housing to the ODD protecting element, to the second housing so as to buffer the external force exerted on the first housing, to prevent the ODD main body from being damaged, and thus to prevent the ODD from being damaged. Meanwhile, the gap between the upper cover and the ODD may be reduced or no gap has to be left therebetween according to such a design according to the invention. Thus, the electric device of the invention is equipped with an ODD (e.g., a thin-type ODD with the dimension of 12.7 millimeters) having a lower cost but a higher height, the overall height of the electric device of the invention may approximate to the height of the conventional electric device equipped with the ultra-thin type ODD having the dimension of 9.5 millimeters. As mentioned above, the electric device of the invention may be equipped with an ODD having a larger thickness but a lower cost without departing from the requirement of the miniaturized product. Hence, the cost of the electric device of the invention is much lower than that of the conventional electric device equipped with the ultra-thin type ODD.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An electric device, comprising:
a first housing;
a second housing, wherein the first housing and the second housing form a containing space;
an ODD (optical disk drive) main body located in the containing space and disposed on the second housing; and
an ODD protecting element, wherein at least one part of the ODD protecting element connects with the second housing, and the ODD protecting element covers the ODD main body.

2. The electric device according to claim 1, wherein the ODD protecting element comprises:
a body covering the ODD main body; and
a connection portion connecting with the body and the second housing.

3. The electric device according to claim 2, wherein the connection portion connects with the second housing by way of engaging, riveting or screwing.

4. The electric device according to claim 2, wherein the body and the connection portion are integrally formed.

5. The electric device according to claim 1, wherein the ODD main body is fixed to at least one of the first housing and the second housing.

6. The electric device according to claim 1, wherein when an external force is applied from the first housing to the ODD protecting element, the ODD protecting element partially transfers the external force to the second housing so as to buffer the external force and thus to prevent the ODD main body from being damaged.

7. An electric device, comprising:
a first housing;
a second housing, wherein the first housing and the second housing form a containing space;
an ODD (optical disk drive) main body located in the containing space and disposed on the second housing; and
an ODD protecting element, wherein at least one part of the ODD protecting element connects with the first housing, and the ODD protecting element covers the ODD main body.

8. The electric device according to claim 7, wherein the ODD protecting element comprises:
a body covering the ODD main body; and
a connection portion connecting with the body and the second housing.

9. The electric device according to claim 8, wherein the connection portion connects with the second housing by way of engaging, riveting or screwing.

10. The electric device according to claim 8, wherein the body and the connection portion are integrally formed.

11. The electric device according to claim 7, wherein the ODD main body is fixed to at least one of the first housing and the second housing.

12. The electric device according to claim 7, wherein when an external force is applied from the first housing to the ODD protecting element, the ODD protecting element partially transfers the external force to the second housing so as to buffer the external force and thus to prevent the ODD main body from being damaged.

13. An electric device, comprising:
a first housing;
a second housing, wherein the first housing and the second housing form a containing space;
an ODD (optical disk drive) main body located in the containing space and disposed on the second housing; and
a protecting element contacting the first housing, wherein when an external force is applied from the first housing to the protecting element, the protecting element partially transfers the external force to the second housing so as to buffer the external force and thus to prevent the ODD main body from being damaged.

14. The electric device according to claim 13, wherein the protecting element comprises:
a body covering the ODD main body; and
a connection portion connecting with the body and the second housing.

15. The electric device according to claim 14, wherein the connection portion connects with the second housing by way of engaging, riveting or screwing.

16. The electric device according to claim 14, wherein the body and the connection portion are integrally formed.
